(19) United States
(12) Patent Application Publication
(10) Pub. No.: US 2025/0300118 A1
(43) Pub. Date: Sep. 25, 2025

(54) HIGH PERFORMANCE SEMICONDUCTOR FAN-OUT PACKAGING

(71) Applicant: Micron Technology, Inc., Boise, ID (US)

(72) Inventors: Owen R. FAY, Meridian, ID (US); Chan H. YOO, Boise, ID (US)

(21) Appl. No.: 19/056,403

(22) Filed: Feb. 18, 2025

Related U.S. Application Data
(60) Provisional application No. 63/567,158, filed on Mar. 19, 2024.

(51) Int. Cl. H01L 23/00

(52) U.S. Cl. CPC H01L 24/24; H01L 24/19; H01L 2224/19; H01L 2224/24101; H01L 2224/245; H01L 2224/25171

(57) ABSTRACT

Implementations described herein relate to various semiconductor device assemblies. In some implementations, an apparatus includes multiple first semiconductor dies and a first mold layer surrounding the multiple first semiconductor dies. A plurality of through mold vias (TMVs) may extend through the first mold layer, and the plurality of TMVs may be filled with conductive filler. The apparatus may include a redistribution layer on the first mold layer, multiple second semiconductor dies electrically connected to the redistribution layer, and a second mold layer surrounding the multiple second semiconductor dies. The redistribution layer may be between the first mold layer and the second mold layer. The apparatus may include a plurality of interconnects attached to the redistribution layer, where the plurality of interconnects are buried in the conductive filler of respective TMVs of the plurality of TMVs.

### CROSS REFERENCE TO RELATED APPLICATION

This Patent Application claims priority to U.S. Provisional Patent Application No. 63/567,158, filed on Mar. 19, 2024, and entitled “HIGH PERFORMANCE SEMICONDUCTOR FAN-OUT PACKAGING.” The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to high performance semiconductor fan-out packaging.

### BACKGROUND

A semiconductor package may include a semiconductor substrate, one or more semiconductor electronic components coupled to and/or embedded in the semiconductor substrate, and a casing formed over the semiconductor substrate to encapsulate the one or more semiconductor electronic components. The one or more semiconductor electronic components may be interconnected by electrical interconnects to form one or more semiconductor devices, such as one or more integrated circuits (ICs) (e.g., one or more dies or chips). For example, the semiconductor electronic components and the electrical interconnects may be fabricated on a semiconductor wafer to form one or more ICs before being diced into dies or chips and then packaged. A semiconductor package may be referred to as a semiconductor chip package that includes one or more ICs. A semiconductor package protects the semiconductor electronic components and the electrical interconnects from damage and includes a mechanism for connecting the semiconductor electronic components and the electrical interconnects to external components (e.g., a circuit substrate), such as via balls, pins, leads, contact pads, or other electrical interconnect structures. A semiconductor device assembly may be or may include a semiconductor package, multiple semiconductor packages, and/or one or more components of a semiconductor package (e.g., one or more semiconductor devices with or without a casing).

An electronic system assembly may include multiple semiconductor packages electrically coupled to a carrier substrate (e.g., circuit substrate). An electronic system assembly may include additional system components electrically coupled to the carrier substrate. The carrier substrate may include electrical interconnects and conductive paths used for interconnecting system components, including the multiple semiconductor packages and other system components of the electronic system assembly. Accordingly, the multiple semiconductor packages may be electrically connected to each other and/or to one or more additional system components via the carrier substrate to form the electronic system assembly. By way of example, other system components may include passive components (e.g., storage capacitors), processing units (e.g., a central processing unit (CPU), a graphics processing unit (GPU), a microprocessor, and/or a microcontroller), control units (e.g., a microcontroller, a memory controller, and/or a power management controller), or one or more other electronic components.

### BRIEF DESCRIPTION OF THE DRAWINGS

FIG. 1 is a diagram of an example apparatus that may be manufactured using techniques described herein.

FIG. 2 is a diagram of an example memory device that may be manufactured using techniques described herein.

FIG. 3 is a diagram of an example apparatus.

FIG. 4 is a diagram of an example apparatus.

FIGS. 5A-5E are diagrams illustrating an example associated with manufacturing an apparatus.

FIG. 6 is a diagram of example equipment used to manufacture various semiconductor packages, memory devices, or similar components described herein.

FIG. 7 is a flowchart of an example method of forming an integrated assembly or memory device having fan-out packaging.

### DETAILED DESCRIPTION

Memory devices capable of high performance, high capacity, and high bandwidth are useful in applications relating to artificial intelligence (AI), data centers, and/or cloud computing, among other examples. Memory devices and similar components may include one or more semiconductor packages, also referred to as semiconductor device assemblies. At a high level, a semiconductor package may include one or more semiconductor devices, such as ICs or similar components. A semiconductor package may employ a fan-out packaging (FOP) technology that utilizes a redistribution layer to redistribute input/output (I/O) connectors associated with one or more semiconductor dies of the semiconductor package. In some examples, multiple semiconductor packages that employ FOP technology may be stacked (e.g., in a package-on-package (PoP) configuration). Generally, such stacked assemblies may be susceptible to chip package interaction stresses and may experience poor solder joint reliability and/or board level reliability. Moreover, because each of the stacked semiconductor packages includes a redistribution layer, manufacture of a stacked assembly may involve multiple bonding operations (e.g., reflow operations, thermal compression bonding (TCB) operations, or the like) to bond semiconductor dies to the multiple redistribution layers, thereby increasing cost and complexity.

Some implementations described herein provide high-performance semiconductor fan-out packaging that provides a high density, small form factor package that may be manufactured with a high package throughput and a relatively low fabrication cost. In some implementations, an apparatus may include multiple semiconductor packages in a stacked arrangement. A bottom package may include a mold layer that encapsulates one or more semiconductor dies, and a plurality of through mold vias (TMVs) may extend through the mold layer. A top package may include one or more semiconductor dies connected to a redistribution layer (e.g., the top package has a FOP configuration), and a plurality of interconnects attached to the redistribution layer. The interconnects may project into conductive filler of the TMVs to physically and electrically connect the top and bottom packages.

Burying the interconnects in the conductive filler provides a strong and reliable physical and electrical connection of the top and bottom packages to enable improved resilience to chip package interaction stresses and improved solder joint reliability and/or board level reliability. Moreover, the redistribution layer, buried between the top and bottom packages, may be the only redistribution layer structure of the assembly, thereby improving solder joint reliability and/or board level reliability as well as reducing a form factor of the apparatus. Furthermore, using a single redistribution layer eliminates the need for additional bonding operations (e.g., reflow operations or TCB operations), thereby reducing a cost and a complexity of the apparatus.

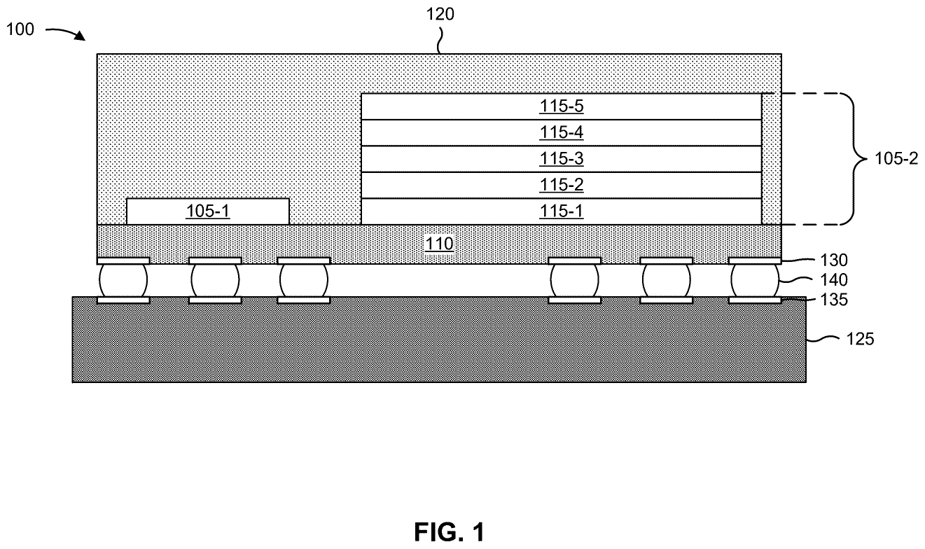

FIG. 1 is a diagram of an example apparatus 100 that may be manufactured using techniques described herein. The apparatus 100 may include any type of device or system that includes one or more integrated circuits 105. For example, the apparatus 100 may include a memory device, a flash memory device, a NAND memory device, a NOR memory device, a random access memory (RAM) device, a read-only memory (ROM) device, a dynamic RAM (DRAM) device, a static RAM (SRAM) device, a solid state drive (SSD), a microchip, and/or a system on a chip (SoC), among other examples. In some cases, the apparatus 100 may be referred to as a semiconductor package, an assembly, a semiconductor device assembly, or an integrated assembly.

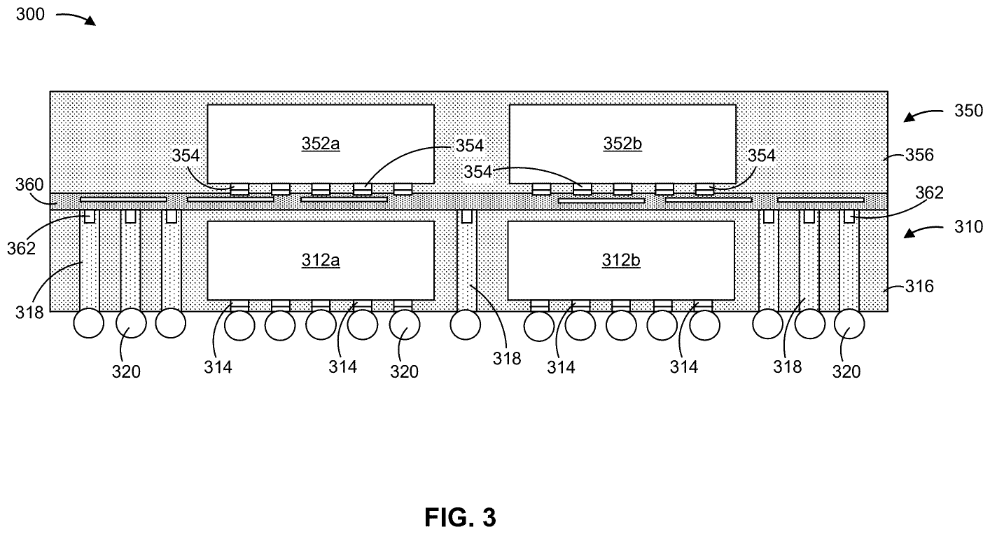

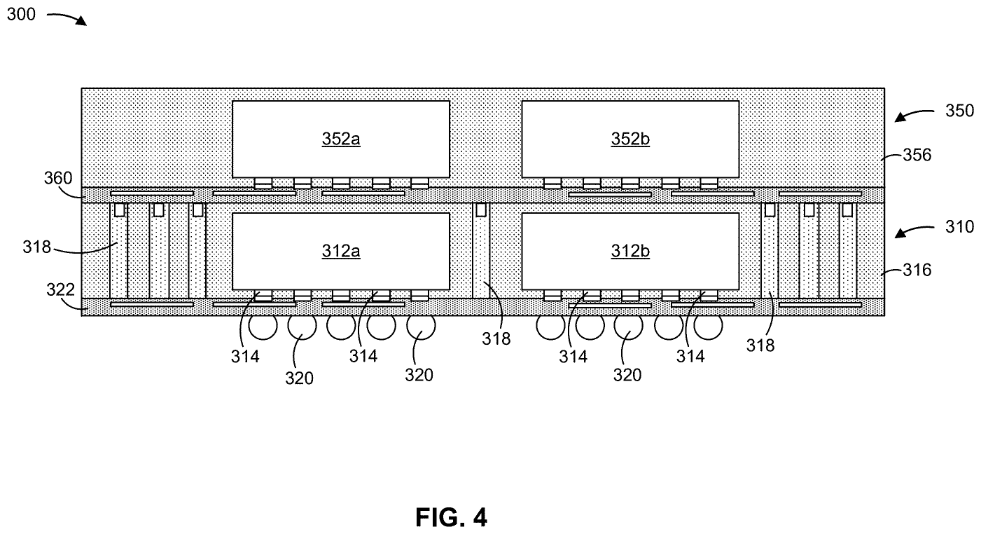

As shown in FIG. 1, the apparatus 100 may include one or more integrated circuits 105, shown as a first integrated circuit 105-1 and a second integrated circuit 105-2, disposed on a substrate 110. An integrated circuit 105 may include any type of circuit, such as an analog circuit, a digital circuit, a radiofrequency (RF) circuit, a power supply, a power management circuit, an I/O chip, an application-specific integrated circuit (ASIC), a field-programmable gate array (FPGA), and/or a memory device (e.g., a NAND memory device, a NOR memory device, a RAM device, or a ROM device). An integrated circuit 105 may be mounted on or otherwise disposed on a surface of the substrate 110. Although the apparatus 100 is shown as including two integrated circuits 105 as an example, the apparatus 100 may include a different number of integrated circuits 105. In some implementations, the substrate 110 may include a redistribution layer, in a similar manner as described in connection with FIGS. 3 and 4.

In some implementations, an integrated circuit 105 may include a single semiconductor die 115 (sometimes called a die), as shown by the first integrated circuit 105-1. In some implementations, an integrated circuit 105 may include multiple semiconductor dies 115 (sometimes called dies), as shown by the second integrated circuit 105-2, which is shown as including five semiconductor dies 115-1 through 115-5.

As shown in FIG. 1, for an integrated circuit 105 that includes multiple dies 115, the dies 115 may be stacked on top of each other to reduce a footprint of the apparatus 100. In some implementations, a spacer may be present between dies 115 that are adjacent to one another in the stack to enable electrical separation and heat dissipation. The stacked dies 115 may include three-dimensional electrical interconnects, such as through-silicon vias (TSVs), to route electrical signals between dies 115. Although the integrated circuit 105-2 is shown as including five dies 115, an integrated circuit 105 may include a different number of dies 115 (e.g., at least two dies 115). A first die 115-1 (sometimes called a bottom die or a base die) may be disposed on the substrate 110, a second die 115-2 may be disposed on the first die 115-1, and so on. Although FIG. 1 shows the dies 115 stacked in a straight stack (e.g., with aligned die edges), in some implementations, the dies 115 may be stacked in a different arrangement, such as a shingle stack (e.g., with die edges that are not aligned, which provides space for wire bonding near the edges of the dies 115).

The apparatus 100 may include a casing 120 that protects internal components of the apparatus 100 (e.g., the integrated circuits 105) from damage and environmental elements (e.g., particles) that can lead to malfunction of the apparatus 100. The casing 120 may be a mold compound, a plastic (e.g., an epoxy plastic), a ceramic, or another type of material depending on the functional requirements for the apparatus 100.

In some implementations, the apparatus 100 may be included as part of a higher-level system (e.g., a computer, a mobile phone, a network device, an SSD, a vehicle, or an Internet of Things device), such as by electrically connecting the apparatus 100 to a circuit board 125, such as a printed circuit board. For example, the substrate 110 may be disposed on the circuit board 125 such that electrical contacts 130 (e.g., bond pads) of the substrate 110 are electrically connected to electrical contacts 135 (e.g., bond pads) of the circuit board 125.

In some implementations, the substrate 110 may be mounted on the circuit board 125 using solder balls 140 (e.g., arranged in a ball grid array), which may be melted to form a physical and electrical connection between the substrate 110 and the circuit board 125. Additionally, or alternatively, the substrate 110 may be mounted on and/or electrically connected to the circuit board 125 using another type of connector, such as pins or leads. Similarly, an integrated circuit 105 may include electrical pads (e.g., bond pads) that are electrically connected to corresponding electrical pads (e.g., bond pads) of the substrate 110 using electrical bonding, such as wire bonding, bump bonding, or the like. The interconnections between an integrated circuit 105, the substrate 110, and the circuit board 125 enable the integrated circuit 105 to receive and transmit signals to other components of the apparatus 100 and/or the higher-level system.

As indicated above, FIG. 1 is provided as an example. Other examples may differ from what is described with regard to FIG. 1.

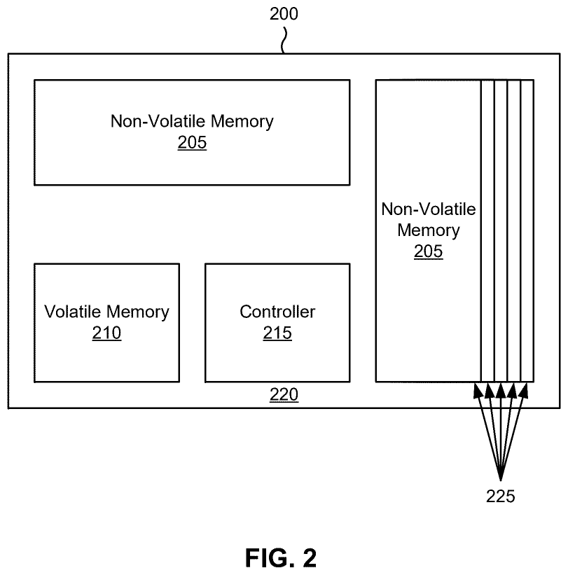

FIG. 2 is a diagram of an example memory device 200 that may be manufactured using techniques described herein. The memory device 200 is an example of the apparatus 100 described above in connection with FIG. 1. The memory device 200 may be any electronic device configured to store data in memory. In some implementations, the memory device 200 may be an electronic device configured to store data persistently in non-volatile memory 205. For example, the memory device 200 may be a hard drive, an SSD, a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, and/or an embedded multimedia card (eMMC) device.

As shown, the memory device 200 may include non-volatile memory 205, volatile memory 210, and a controller 215. The components of the memory device 200 may be mounted on or otherwise disposed on a substrate 220. In some implementations, the non-volatile memory 205 includes a single die. Additionally, or alternatively, the non-volatile memory 205 may include multiple dies, such as stacked semiconductor dies 225 (e.g., in a straight stack, a shingle stack, or another type of stack), as described above in connection with FIG. 1.

The non-volatile memory 205 may be configured to maintain stored data after the memory device 200 is powered off. For example, the non-volatile memory 205 may include NAND memory or NOR memory. The volatile memory 210 may require power to maintain stored data and may lose stored data after the memory device 200 is powered off. For example, the volatile memory 210 may include one or more latches and/or RAM, such as DRAM and/or SRAM. As an example, the volatile memory 210 may cache data read from or to be written to non-volatile memory 205, and/or may cache instructions to be executed by the controller 215.

The controller 215 may be any device configured to communicate with the non-volatile memory 205, the volatile memory 210, and a host device (e.g., via a host interface of the memory device 200). For example, the controller 215 may include a memory controller, a system controller, an ASIC, an FPGA, a processor, a microcontroller, and/or one or more processing components. In some implementations, the memory device 200 may be included in a system that includes the host device. The host device may include one or more processors configured to execute instructions and store data in the non-volatile memory 205.

The controller 215 may be configured to control operations of the memory device 200, such as by executing one or more instructions (sometimes called commands). For example, the memory device 200 may store one or more instructions as firmware, and the controller 215 may execute those one or more instructions. Additionally, or alternatively, the controller 215 may receive one or more instructions from a host device via a host interface, and may execute those one or more instructions. For example, the controller 215 may transmit signals to and/or receive signals from the non-volatile memory 205 and/or the volatile memory 210 based on the one or more instructions, such as to transfer data to (e.g., write or program), to transfer data from (e.g., read), and/or to erase all or a portion of the non-volatile memory 205 (e.g., one or more memory cells, pages, sub-blocks, blocks, or planes of the non-volatile memory 205).

As indicated above, FIG. 2 is provided as an example. Other examples may differ from what is described with regard to FIG. 2. The number and arrangement of components shown in FIG. 2 are provided as an example. In practice, there may be additional components, fewer components, different components, or differently arranged components than those shown in FIG. 2.

FIG. 3 is a diagram of an example apparatus 300. The apparatus 300 may be a semiconductor device assembly.

The apparatus 300 may include a first semiconductor package 310 and a second semiconductor package 350 in a stacked arrangement. For example, the second semiconductor package 350 may be stacked on the first semiconductor package 310. The first semiconductor package 310 and/or the second semiconductor package may be multi-chip packages, as described herein.

The first semiconductor package 310 may include one or more first semiconductor dies 312 (shown as semiconductor dies 312a and 312b). For example, the first semiconductor package 310 may include multiple first semiconductor dies 312, such as two semiconductor dies, four semiconductor dies, or a different quantity of semiconductor dies. Similarly, the second semiconductor package 350 may include one or more second semiconductor dies 352 (shown as semiconductor dies 352a and 352b). For example, the second semiconductor package 350 may include multiple second semiconductor dies 352, such as two semiconductor dies, four semiconductor dies, or a different quantity of semiconductor dies. A quantity of the first semiconductor dies 312 may be the same as, or different from, a quantity of the second semiconductor dies 352. In some implementations, a die thickness of the first semiconductor dies 312 and/or the second semiconductor dies 352 may be in a range from approximately 50 micrometers (μm) to approximately 250 μm.

The first semiconductor dies 312 and the second semiconductor dies 352 may be memory dies (e.g., DRAM dies, NAND dies, SRAM dies, and/or NOR dies, among other examples). For example, the first semiconductor dies 312 and the second semiconductor dies 352 may be copies of each other. Alternatively, the first semiconductor dies 312 may include at least two different types of memory dies and/or the second semiconductor dies 352 may include at least two different types of memory dies. In some implementations, the first semiconductor dies 312 may include one or more logic dies (and the second semiconductor dies 352 may include one or more memory dies) and/or the second semiconductor dies 352 may include one or more logic dies (and the first semiconductor dies 312 may include one or more memory dies). For example, one of the first semiconductor package 310 or the second semiconductor package 350 may be a logic package, and the other of the first semiconductor package 310 or the second semiconductor package 350 may be a memory package.

A plurality of direct chip attachment (DCA) bumps 314, such as microbumps, solder balls, pillars, or the like, may be physically and electrically connected to each of the first semiconductor dies 312, and a plurality of DCA bumps 354 may be physically and electrically connected to each of the second semiconductor dies 352. The DCA bumps 314, 354 may include solder caps. The DCA bumps 314, 354 may be configured to electrically connect the first semiconductor dies 312 and the second semiconductor dies 352, respectively, to one or more other components of the apparatus 300 or external to the apparatus 300 (e.g., via the solder).

In some implementations, each of the first semiconductor dies 312 may include an integrated redistribution layer (not shown). The integrated redistribution layer may be configured to fan-in I/O connectors of the semiconductor die 312 (e.g., the DCA bumps 314) to a particular pitch (e.g., a chip scale package (CSP) pitch, such as approximately 0.3 millimeters (mm)). Accordingly, having integrated redistribution layers in the first semiconductor dies 312 allows for a package-level redistribution layer to be eliminated from the first semiconductor package 310.

The first semiconductor package 310 may include a first mold layer 316 surrounding the first semiconductor dies 312. Similarly, the second semiconductor package 350 may include a second mold layer 356 surrounding the second semiconductor dies 352. The first mold layer 316 may fully encapsulate the first semiconductor dies 312, including the DCA bumps 314 associated with the first semiconductor dies 312. Similarly, the second mold layer 356 may fully encapsulate second semiconductor dies 352, including the DCA bumps 354 associated with the second semiconductor dies 352. By fully encapsulating the semiconductor dies 312, 352, the mold layers 316, 356 mitigate chip package interaction stresses.

A plurality of TMVs 318 may extend through the first mold layer 316. The TMVs 318 are filled with conductive filler. A TMV 318 “filled” with conductive filler may be partially filled with conductive filler or completely filled with conductive filler. The conductive filler may include conductive paste (e.g., silver paste or silver sintering paste), solder paste (e.g., a high temperature solder, such as tin-gold solder), and/or a metal filler (e.g., copper). The TMVs 318 may include a first one or more TMVs 318 at a periphery of the first semiconductor dies 312 (e.g., defining a border around the first semiconductor dies 312) and/or a second one or more TMVs 318 between semiconductor dies of the first semiconductor dies 312. In some implementations, a pitch of the TMVs 318 may match a pitch of the DCA bumps 314 associated with the first semiconductor dies 312 (e.g., approximately 0.3 mm).

The second semiconductor package 350 may include a redistribution layer 360 (e.g., the second semiconductor package may have a FOP configuration). The redistribution layer 360 may be arranged between the first mold layer 316 and the second mold layer 356 (e.g., the redistribution layer 360 is a buried redistribution layer). The second semiconductor dies 352 may be arranged on and electrically connected to (e.g., via the DCA bumps 354) the redistribution layer 360. The redistribution layer 360 may include a dielectric material (e.g., polyimide or SiO₂, among other examples) and one or more electrical connections, such as conductive traces, pads, or the like, used to electrically couple the redistribution layer 360 to the second semiconductor dies 352 and/or the TMVs 318. The redistribution layer 360 may be configured to redistribute I/O connectors of the second semiconductor dies 352 to other locations of the apparatus 300.

In some implementations, a dual-sided die configuration may be employed for the redistribution layer 360. Here, the first semiconductor dies 312 may include one or more additional semiconductor dies 312 that are arranged on and electrically connected to (e.g., via the DCA bumps 314) a first surface of the redistribution layer 360 (e.g., that faces the first mold layer 316), and the second semiconductor dies 352 may be arranged on and electrically connected to (e.g., via the DCA bumps 354) a second surface of the redistribution layer 360 (e.g., that faces the second mold layer 356) that is opposite the first surface. Accordingly, in some implementations, the first semiconductor dies 312 may include one or more semiconductor dies 312 positioned with their DCA bumps 314 facing away from the redistribution layer 360 (e.g., in the orientation shown in FIG. 3) and one or more semiconductor dies 312 positioned with their DCA bumps 314 facing the redistribution layer 360 (not shown), such that the first semiconductor dies 312 include one or more sets of semiconductor dies 312 arranged back-to-back. In this configuration, the first semiconductor package 310 may include four of the first semiconductor dies 312, for a total of six semiconductor dies in the apparatus 300 (including two of the second semiconductor dies 352).

A plurality of interconnects 362 may be physically and electrically connected to the redistribution layer 360. For example, the second semiconductor dies 352 may be arranged on a first surface of the redistribution layer 360, and the interconnects 362 may extend from a second surface of the redistribution layer 360 opposite the first surface. The interconnects 362 may be electrically conductive. The interconnects 362 may include DCA bumps, such as conductive posts (e.g., copper posts) or pillars. Each interconnect 362 may be sized to fit within an opening containing a TMV 318 (e.g., a diameter of an interconnect 362 is smaller than a diameter of the opening). For example, the opening for a TMV 318 may have a diameter of approximately 100 μm, and an interconnect 362 may have a diameter of approximately 30 μm. As another example, the opening for a TMV 318 may have a diameter in a range from 10 μm to 300 μm, and an interconnect 362 may have a diameter in a range from 3 μm to 150 μm (provided that the diameter of the interconnect 362 is smaller than the diameter of the opening). Accordingly, the interconnects 362 may be buried in (e.g., project into) the conductive filler of the TMVs 318, thereby burying the interconnects 362 into the TMVs 318 themselves. For example, the interconnects 362 may be buried in the conductive filler of respective TMVs 318. Burying the interconnects 362 in the conductive filler provides a strong physical connection of the first semiconductor package 310 and the second semiconductor package 350. In this way, the apparatus 300 may exhibit improved resilience to chip package interaction stresses, improved solder joint reliability, and/or improved board level reliability.

As shown, the apparatus 300 may include a plurality of solder balls 320 (e.g., arranged in a ball grid array) configured to mount and electrically connect the apparatus 300 to a substrate, such as a circuit board. The solder balls 320 may include a first plurality of solder balls 320 attached to respective TMVs 318 (e.g., in a bump-on-via arrangement) and a second plurality of solder balls 320 attached to respective DCA bumps 314 of the first semiconductor dies 312 (e.g., in a bump-on-bump arrangement). The solder balls 320 on the TMVs 318 facilitate electrical interconnection for the second semiconductor dies 352, and the solder balls 320 on the DCA bumps 314 facilitate electrical interconnection for the first semiconductor dies 312. Moreover, the solder balls 320 provide low-stress interconnection, thereby improving solder joint reliability and board level reliability with respect to chip package interaction.

Although the first semiconductor package 310 and the second semiconductor package 350 are described herein as separate packages, the physical connection of the first semiconductor package 310 and the second semiconductor package 350 (e.g., achieved by burying the interconnects 362 in the conductive filler of the TMVs 318) may form an integrated package assembly. In some implementations, the apparatus 300 may include more than two stacked semiconductor packages, such as three stacked semiconductor packages, four stacked semiconductor packages, etc. For example, with three stacked semiconductor packages, the second semiconductor package 350 may include TMVs as described herein, and a third semiconductor package, stacked on the second semiconductor package 350, may include a redistribution layer with interconnects that are buried into conductive filler of the TMVs of the second semiconductor package 350.

As indicated above, FIG. 3 is provided as an example. Other examples may differ from what is described with respect to FIG. 3.

FIG. 4 is a diagram of an alternative example of the apparatus 300. As shown in FIG. 4, the apparatus 300 may include an additional redistribution layer 322 (e.g., as part of the first semiconductor package 310). The additional redistribution layer 322 may be arranged beneath the first mold layer 316. The first semiconductor dies 312 may be arranged on and electrically connected to (e.g., via the DCA bumps 314) the additional redistribution layer 322. Moreover, the TMVs 318 may electrically connect to the additional redistribution layer 322. For example, the TMVs 318 may extend between and electrically connect the redistribution layer 360 and the additional redistribution layer 322. The additional redistribution layer 322 may be configured to fan-in I/O connectors of the apparatus 300 (e.g., in accordance with an interconnection standard, a ball grid array standard, or the like). The solder balls 320 may be attached and electrically connected to the additional redistribution layer 322.

As indicated above, FIG. 4 is provided as an example. Other examples may differ from what is described with respect to FIG. 4.

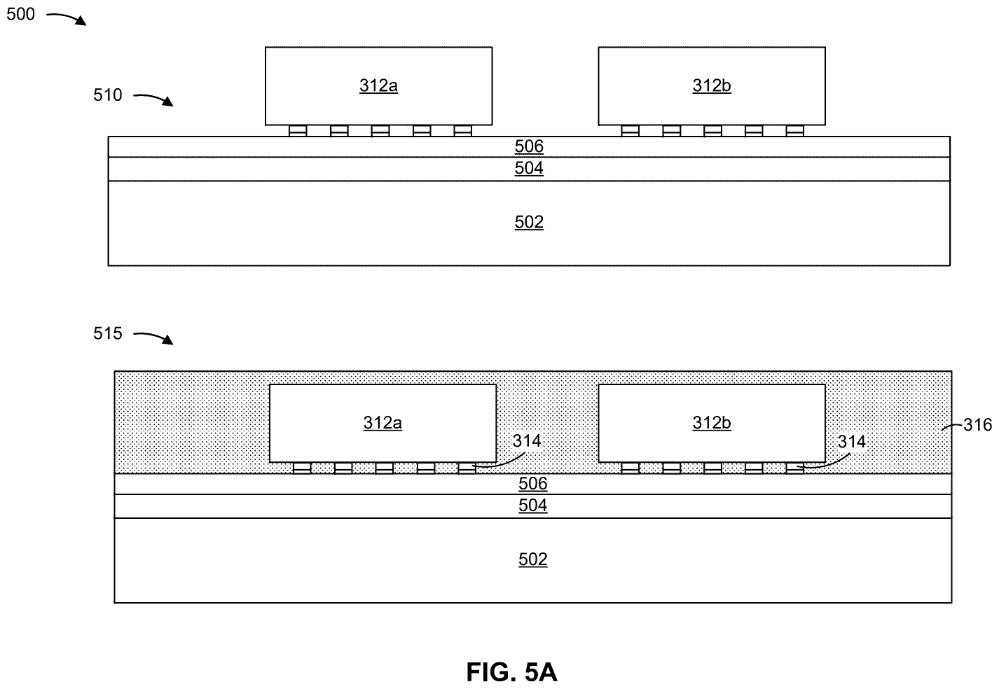

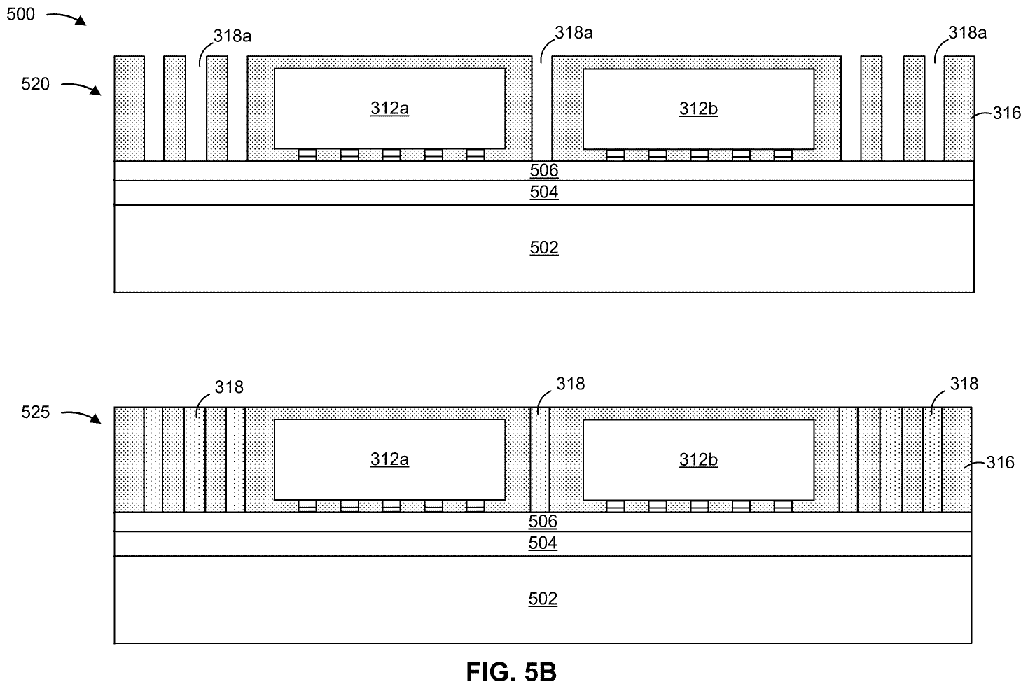

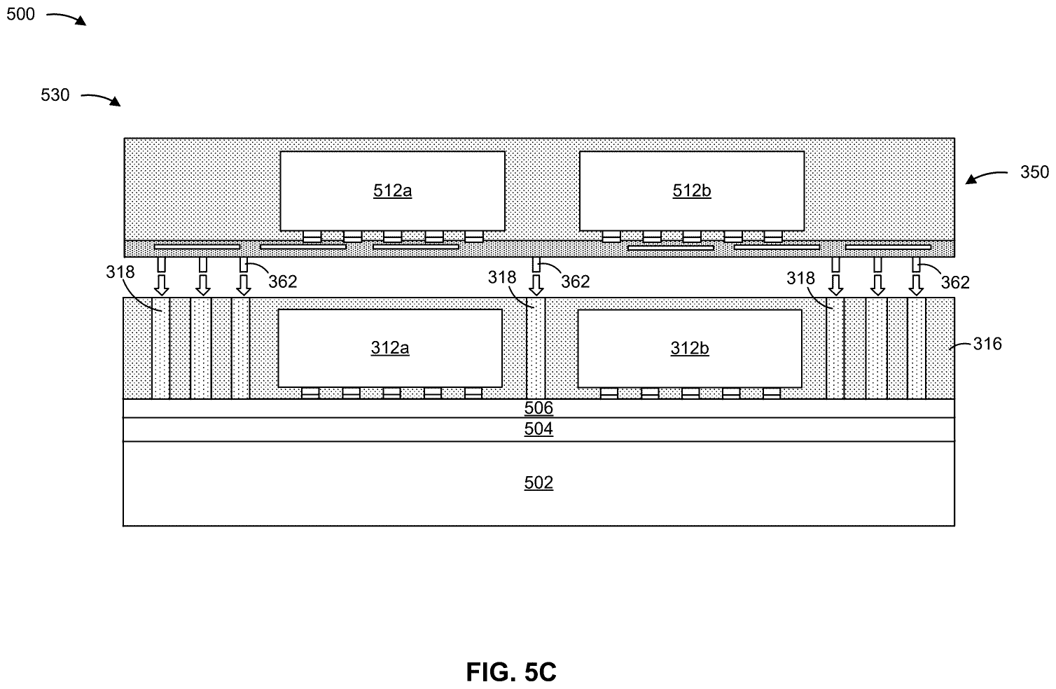

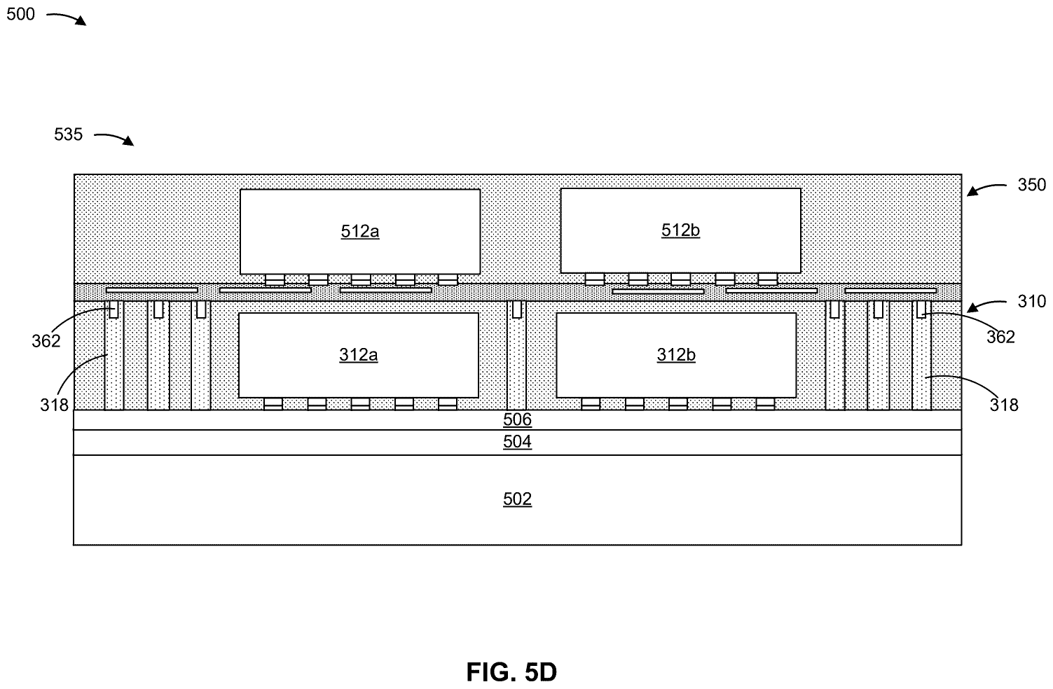

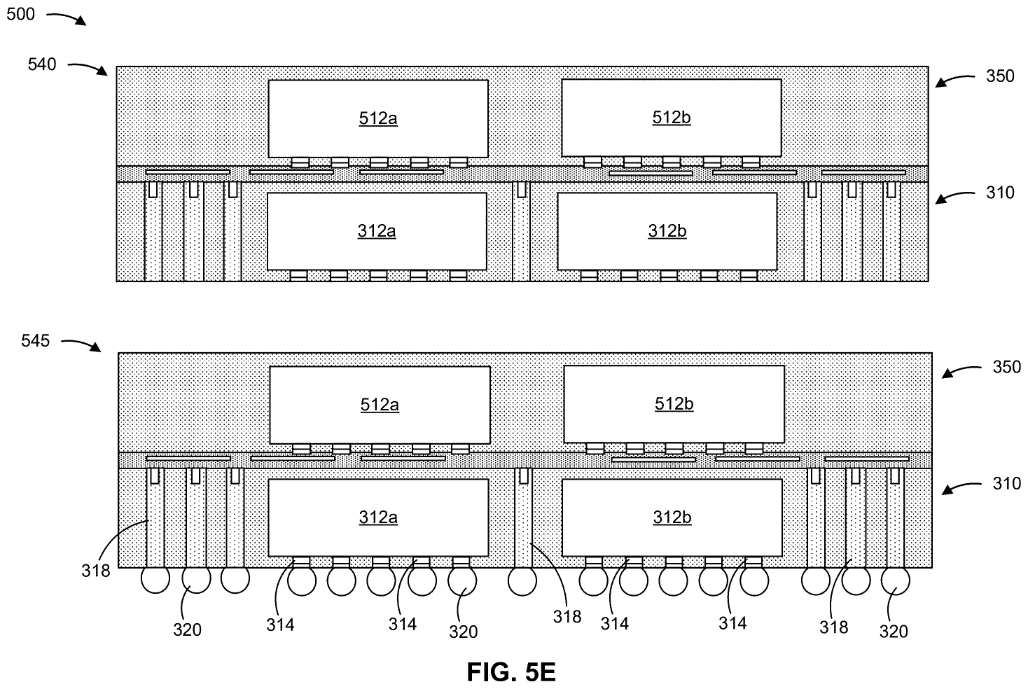

FIGS. 5A-5E are diagrams illustrating an example 500 associated with manufacturing the apparatus 300 (e.g., a semiconductor device assembly or a semiconductor package). As shown in FIG. 5A, the apparatus 300 may be manufactured on a carrier 502. In some implementations, the carrier 502 may be a wafer-shaped carrier, a panel-shaped carrier, or a strip-shaped carrier. The carrier 502 may be constructed from any suitable material used in a semiconductor package manufacturing process. For example, the carrier 502 may be a stiff material that provides control and reduction of wafer warpage during manufacturing of the apparatus. In some implementations, the carrier 502 may be a glass carrier, which may aid in a debonding process (e.g., a laser-debonding process or other debonding process). In some implementations, the carrier 502 may be laminated or otherwise coated with a sacrificial layer 504 (e.g., a release film), also referred to as a release layer, and/or an adhesive layer 506 (e.g., a die attach film). The sacrificial layer 504 may aid during a debonding process by permitting the carrier 502 to be easily removed from a package wafer after wafer formation.

As shown by reference number 510, the first semiconductor dies 312 may be placed on the carrier 502. In some implementations, as described herein, the first semiconductor dies 312 may be arranged on the additional redistribution layer 322. Accordingly, in some implementations, prior to placing the first semiconductor dies 312, the additional redistribution layer 322 may be formed on the carrier 502, and the first semiconductor dies 312 may be placed on the additional redistribution layer 322, which is on the carrier 502. Moreover, the first semiconductor dies 312 may be bonded to the additional redistribution layer 322 (e.g., via the DCA bumps 314) by performing a reflow process, a thermal compression bonding (TCB) process, or a similar process.

As shown by reference number 515, the first mold layer 316 may be formed over the first semiconductor dies 312. For example, the first mold layer 316 may surround the first semiconductor dies 312, including underneath the first semiconductor dies 312 between the DCA bumps 314. A compression molding process may be performed to form the first mold layer 316. The compression molding process may include compressing a mold compound (e.g., an epoxy mold compound) on the first semiconductor dies 312. The mold compound may be a moldable underfill (MUF) material to facilitate the mold compound surrounding the DCA bumps 314. The molding of the first mold layer 316 may be a panel-level process or a wafer-level process.

As shown in FIG. 5B, and by reference number 520, openings 318a for the TMVs 318 may be formed through the first mold layer 316. A laser ablation process may be performed to form the openings 318a. As shown by reference number 525, the openings 318a may be filled with conductive filler to form the TMVs 318 through the first mold layer 316. Filling the openings 318a with the conductive filler may include a micro-jetting process (e.g., using a conductive paste, a solder paste, a copper paste, or the like, as the conductive filler). In some implementations, the conductive filler may be a metal (e.g., copper) fill formed by physical vapor deposition (PVD) of a metal seed with metal electrochemical deposition (ECD). In some examples, reference numbers 510 through 525 describe the formation of the first semiconductor package 310.

As shown in FIG. 5C, and by reference number 530, the second semiconductor package 350 may be placed on (e.g., stacked on) the first mold layer 316 (e.g., on the first semiconductor package 310), which buries the interconnects 362 in the conductive filler of the TMVs 318. For example, the second semiconductor package 350 may be placed before the conductive filler has set or cured to allow the interconnects 362 to penetrate into the conductive filler. As shown in FIG. 5D, and by reference number 535, with the interconnects 362 buried into the TMVs 318, the conductive filler may be allowed to set or may be cured to harden the conductive filler and bond the second semiconductor package 350 to the first semiconductor package 310.

The second semiconductor package 350 may be separately fabricated prior to being stacked on the first semiconductor package 310. For example, the redistribution layer 360 may be formed on a separate carrier (e.g., that may be coated with a sacrificial layer and/or an adhesive layer), and the second semiconductor dies 352 may be placed on the redistribution layer 360 and bonded to the redistribution layer 360 (e.g., via the DCA bumps 354) by performing a reflow process, a TCB process, or a similar process. The second mold layer 356 may be formed over the second semiconductor dies 352 to surround the second semiconductor dies 352, in a similar manner as the first mold layer 316. The carrier may be removed from the redistribution layer 360, and the interconnects 362 may be applied to the redistribution layer 360 (e.g., using electroplating or a similar process).

As shown in FIG. 5E, and by reference number 540, the carrier 502 (e.g., along with the sacrificial layer 504 and/or the adhesive layer 506) may be removed from the first semiconductor package 310 (e.g., resulting in a standalone package wafer and/or panel). For example, the carrier 502 may be removed using a debonding process (e.g., a laser debonding process). In some implementations, the debonding process may include cleaning a bottom surface of the first semiconductor package 310 to remove residual adhesives or similar contaminants.

As shown by reference number 545, the solder balls 320 may be applied to the first semiconductor package 310. In implementations that do not employ the additional redistribution layer 322, the solder balls 320 may be applied directly to the TMVs 318 and the DCA bumps 314. In implementations that employ the additional redistribution layer 322, the solder balls 320 may be applied to the additional redistribution layer 322. The solder balls 320 may be applied using a ball drop process, a screen printing process, or a similar process. The solder balls 320 may ultimately be used to provide electrical connectivity of the apparatus 300 to a circuit board or similar structure. In some implementations, after application of the solder balls 320, the standalone package wafer and/or panel may be singulated (e.g., by dicing) into multiple apparatuses 300.

As indicated above, FIGS. 5A-5E are provided as an example. Other examples may differ from what is described with respect to FIGS. 5A-5E.

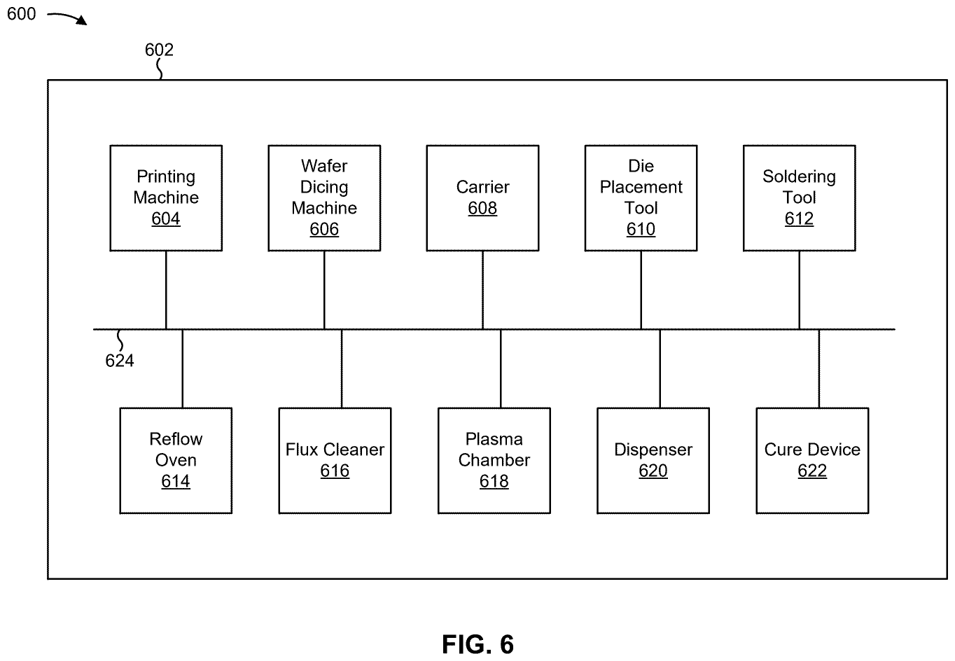

FIG. 6 is a diagram of example equipment 600 used to manufacture various semiconductor packages, memory devices, or similar components described herein. In some implementations, the equipment 600 may be used to manufacture the apparatus 300 using a manufacturing process, such as the manufacturing process described above in connection with FIGS. 5A-5E. As shown in FIG. 6, the equipment 600 may include a packaging system 602. The packaging system 602 may include one or more devices or tooling, such as a printing machine 604, a wafer dicing machine 606, a carrier 608, a die placement tool 610, a soldering tool 612, a reflow oven 614, a flux cleaner 616, a plasma chamber 618, a dispenser 620, and/or a cure device 622. Multiple devices may be physically or communicatively coupled to one another. For example, multiple devices may interconnect via wired connections and/or wireless connections, such as via a bus 624. Additionally, or alternatively, multiple devices may form part of an electronics assembly manufacturing line.

The printing machine 604 may be a device capable of printing patterns in a material such as silicon, a dielectric material, or a similar material, for purposes of forming an integrated circuit or the like. In some implementations, the printing machine 604 may be a lithography device capable of printing patterns in a material to form an integrated circuit. Additionally, or alternatively, the printing machine 604 may be capable of applying solder or other electrically conductive material to form a portion of an electrical connection to be formed between a die and a substrate. For example, the printing machine 604 may be capable of applying a grid of solder bumps to a die, which will align with a grid of bump pads on a substrate during a flip chip attachment process, or the like.

The wafer dicing machine 606 may be a device capable of dicing a die, such as a microcontroller, a memory die, or other semiconductor die, from a wafer. In some implementations, the wafer dicing machine 606 may include one or more blades and/or one or more lasers to dice a die from the wafer.

The carrier 608 may be a device capable of supporting and/or carrying a substrate during a die and/or chip attachment process, or during a similar process. The carrier 608 may be constructed from a non-contaminating material, such as quartz, glass, or a similar material, and may be capable of withstanding high temperatures. In that regard, the carrier 608 may be capable of carrying a substrate and/or one or more die through one or more ovens, such as the reflow oven 614 and/or the cure device 622.

The die placement tool 610 may be a high-precision tool capable of placing a die onto a substrate. In some implementations, the die placement tool 610 may be capable of flipping a flip chip die during a placement process, such that an active surface of the flip chip die, which may be facing up during preliminary manufacturing steps, may face the substrate during the flip chip die placement process. In some implementations, the die placement tool 610 may include one or more sensors capable of aligning bump bonds on a die with bond pads on a substrate during a flip chip die attachment process.

The soldering tool 612 may be capable of forming one or more solder connections between components of a semiconductor package. For example, the soldering tool 612 may be capable of forming wire bond connections between components of a semiconductor package by soldering wires connecting wire bond bands from one component to wire bond pads of another component. In some implementations, the soldering tool may be capable of applying a solder mask over one or more electrical connections and/or solder joints.

The reflow oven 614 may be capable of heating components to a suitable temperature to cause a reflow of solder or other bonding material, thereby causing the solder or similar material to melt and make an electrical connection between two components.

The flux cleaner 616 may be a device capable of removing residual flux from a soldering process. In some implementations, the flux cleaner 616 may include a heater capable of removing residual flux through a heat treatment process. Additionally, or alternatively, the flux cleaner 616 may include a nozzle or similar device capable of applying a cleaning agent to a component in a die attachment process in order to remove residual flux therefrom.

The plasma chamber 618 may be a device capable of providing plasma treatment to a component. In some implementations, the plasma chamber 618 may be capable of directly or indirectly applying a plasma stream to an area of a component, such as for purposes of preparing the area on the component for receiving an epoxy underfill, or the like.

The dispenser 620 may be a device capable of dispensing a mold compound around a die or similar component. In some implementations, the dispenser 620 may be capable of dispensing a mold compound (e.g., an epoxy mold compound) during a compression molding process. In some implementations, the dispenser 620 may include a dispensing needle capable of applying an epoxy underfill by capillary action under pressure, such as by dispensing underfill material around a periphery of a die such that the underfill material flows beneath the die and fills a space between the die and substrate.

The cure device 622 may be a device capable of curing a mold compound, such as an epoxy mold compound, an epoxy underfill material, an MUF, or a similar material. In some implementations, the cure device 622 may be an oven configured to heat a mold compound to a suitable curing temperature. Additionally, or alternatively, the cure device 622 may be capable of curing a mold compound via a chemical reaction, by the application of ultraviolet light, by the application of other radiation, or the like.

The number and arrangement of devices and networks shown in FIG. 6 are provided as an example. In practice, there may be additional devices, fewer devices, different devices, or differently arranged devices than those shown in FIG. 6. Furthermore, two or more devices shown in FIG. 6 may be implemented within a single device, or a single device shown in FIG. 6 may be implemented as multiple, distributed devices. Additionally, or alternatively, a set of devices (e.g., one or more devices) of equipment 600 may perform one or more functions described as being performed by another set of devices of equipment 600.

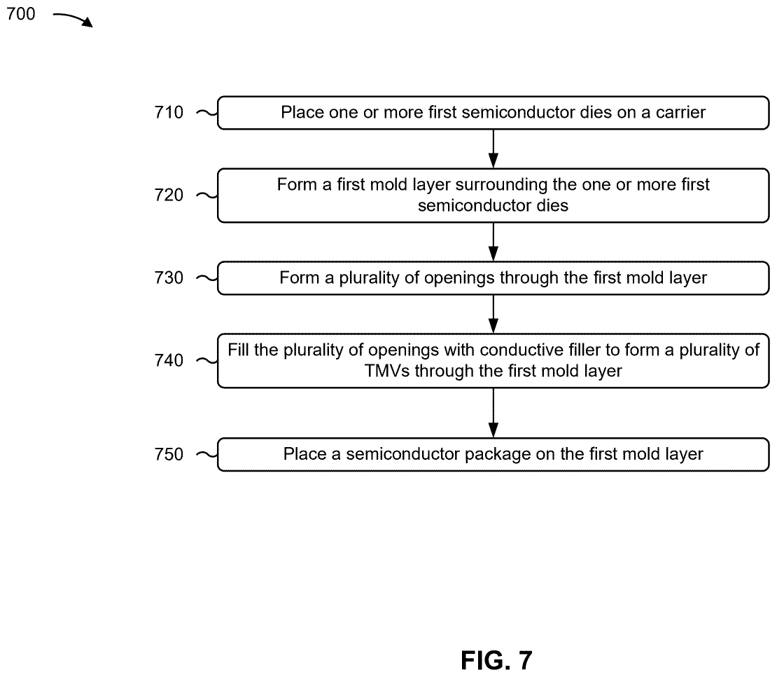

FIG. 7 is a flowchart of an example method 700 of forming an integrated assembly or memory device having fan-out packaging. In some implementations, one or more process blocks of FIG. 7 may be performed by various semiconductor manufacturing equipment, such as the semiconductor manufacturing equipment described above in connection with FIG. 6.

As shown in FIG. 7, the method 700 may include placing one or more first semiconductor dies on a carrier (block 710). As further shown in FIG. 7, the method 700 may include forming a first mold layer surrounding the one or more first semiconductor dies (block 720). As further shown in FIG. 7, the method 700 may include forming a plurality of openings through the first mold layer (block 730). As further shown in FIG. 7, the method 700 may include filling the plurality of openings with conductive filler to form a plurality of TMVs through the first mold layer (block 740). As further shown in FIG. 7, the method 700 may include placing a semiconductor package on the first mold layer (block 750). The semiconductor package may include a redistribution layer, one or more second semiconductor dies electrically connected to the redistribution layer, a second mold layer surrounding the one or more second semiconductor dies, and a plurality of interconnects attached to the redistribution layer. Placing the semiconductor package on the first mold layer may bury the plurality of interconnects in the conductive filler of respective TMVs of the plurality of TMVs.

The method 700 may include additional aspects, such as any single aspect or any combination of aspects described below and/or in connection with one or more other methods described elsewhere herein.

In a first aspect, the method 700 includes removing the carrier, and applying a plurality of solder balls to respective TMVs of the plurality of TMVs and to respective DCA bumps of the one or more first semiconductor dies.

In a second aspect, alone or in combination with the first aspect, the method 700 includes forming an additional redistribution layer on the carrier, where the one or more first semiconductor dies are placed on the additional redistribution layer that is on the carrier.

In a third aspect, alone or in combination with one or more of the first and second aspects, the method 700 includes removing the carrier, and applying a plurality of solder balls to the additional redistribution layer.

In a fourth aspect, alone or in combination with one or more of the first through third aspects, the method 700 includes forming the redistribution layer, placing the one or more second semiconductor dies on the redistribution layer, forming the second mold layer surrounding the one or more second semiconductor dies, and applying the plurality of interconnects to the redistribution layer.

Although FIG. 7 shows example blocks of the method 700, in some implementations, the method 700 may include additional blocks, fewer blocks, different blocks, or differently arranged blocks than those depicted in FIG. 7. In some implementations, the method 700 may include forming the apparatus 300, an integrated assembly that includes the apparatus 300, any part described herein of the apparatus 300, and/or any part described herein of an integrated assembly that includes the structure 300. For example, the method 700 may include forming one or more of the components 310 through 322 and/or 350 through 362.

In some implementations, a semiconductor device assembly includes a first semiconductor package, including one or more first semiconductor dies; and a first mold layer surrounding the one or more first semiconductor dies, where a plurality of TMVs extend through the first mold layer, and where the plurality of TMVs are filled with conductive filler. The semiconductor device assembly may include a second semiconductor package, stacked on the first semiconductor package, including a redistribution layer; one or more second semiconductor dies electrically connected to the redistribution layer; a second mold layer surrounding the one or more second semiconductor dies; and a plurality of interconnects attached to the redistribution layer, where the plurality of interconnects project into the conductive filler of respective TMVs of the plurality of TMVs.

In some implementations, an apparatus includes multiple first semiconductor dies; a first mold layer surrounding the multiple first semiconductor dies, where a plurality of TMVs extend through the first mold layer, and where the plurality of TMVs are filled with conductive filler; a redistribution layer on the first mold layer; multiple second semiconductor dies electrically connected to the redistribution layer; a second mold layer surrounding the multiple second semiconductor dies, where the redistribution layer is between the first mold layer and the second mold layer; and a plurality of interconnects attached to the redistribution layer, wherein the plurality of interconnects are buried in the conductive filler of respective TMVs of the plurality of TMVs.

In some implementations, a method includes placing one or more first semiconductor dies on a carrier; forming a first mold layer surrounding the one or more first semiconductor dies; forming a plurality of openings through the first mold layer; filling the plurality of openings with conductive filler to form a plurality of TMVs through the first mold layer; and placing a semiconductor package on the first mold layer. The semiconductor package may include a redistribution layer; one or more second semiconductor dies electrically connected to the redistribution layer; a second mold layer surrounding the one or more second semiconductor dies; and a plurality of interconnects attached to the redistribution layer, where placing the semiconductor package on the first mold layer buries the plurality of interconnects in the conductive filler of respective TMVs of the plurality of TMVs.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.”

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. An apparatus, comprising:
multiple first semiconductor dies;
a first mold layer surrounding the multiple first semiconductor dies,
wherein a plurality of through mold vias (TMVs) extend through the first mold layer, and
wherein the plurality of TMVs are filled with conductive filler;
a redistribution layer on the first mold layer;
multiple second semiconductor dies electrically connected to the redistribution layer;
a second mold layer surrounding the multiple second semiconductor dies,
wherein the redistribution layer is between the first mold layer and the second mold layer; and
a plurality of interconnects attached to the redistribution layer,
wherein the plurality of interconnects are buried in the conductive filler of respective TMVs of the plurality of TMVs.

2. The apparatus of claim 1, wherein the plurality of TMVs include a first one or more TMVs at a periphery of the multiple first semiconductor dies and a second one or more TMVs between semiconductor dies of the multiple first semiconductor dies.

3. The apparatus of claim 1, wherein the conductive filler comprises conductive paste or solder paste.

4. The apparatus of claim 1, further comprising:
a first plurality of solder balls attached to respective TMVs of the plurality of TMVs and a second plurality of solder balls attached to respective direct chip attachment (DCA) bumps of the multiple first semiconductor dies.

5. The apparatus of claim 1, further comprising:
an additional redistribution layer,
wherein the one or more first semiconductor dies are electrically connected to the additional redistribution layer; and
a plurality of solder balls attached to the additional redistribution layer.

6. The apparatus of claim 1, wherein the plurality of interconnects comprise a plurality of conductive posts.

7. The apparatus of claim 1, wherein an interconnect, of the plurality of interconnects, is sized to fit within an opening containing a TMV of the plurality of TMVs.

8. A semiconductor device assembly, comprising:
a first semiconductor package, comprising:
one or more first semiconductor dies; and
a first mold layer surrounding the one or more first semiconductor dies,
wherein a plurality of through mold vias (TMVs) extend through the first mold layer, and
wherein the plurality of TMVs are filled with conductive filler; and
a second semiconductor package, stacked on the first semiconductor package, comprising:
a redistribution layer;
one or more second semiconductor dies electrically connected to the redistribution layer;
a second mold layer surrounding the one or more second semiconductor dies; and
a plurality of interconnects attached to the redistribution layer,
wherein the plurality of interconnects project into the conductive filler of respective TMVs of the plurality of TMVs.

9. The semiconductor device assembly of claim 8, further comprising:
a first plurality of solder balls attached to respective TMVs of the plurality of TMVs and a second plurality of solder balls attached to respective direct chip attachment (DCA) bumps of the one or more first semiconductor dies.

10. The semiconductor device assembly of claim 8, further comprising:
an additional redistribution layer,
wherein the one or more first semiconductor dies are electrically connected to the additional redistribution layer, and
wherein the plurality of TMVs electrically connect the redistribution layer and the additional redistribution layer.

11. The semiconductor device assembly of claim 10, further comprising:
a plurality of solder balls attached to the additional redistribution layer.

12. The semiconductor device assembly of claim 8, wherein the one or more first semiconductor dies comprise multiple first semiconductor dies and the one or more second semiconductor dies comprise multiple second semiconductor dies.

13. The semiconductor device assembly of claim 8, wherein the redistribution layer is on the first mold layer.

14. The semiconductor device assembly of claim 8, wherein the plurality of interconnects comprise a plurality of conductive posts.

15. The semiconductor device assembly of claim 8, wherein the one or more first semiconductor dies and the one or more second semiconductor dies comprise memory dies.

16. A method, comprising:
placing one or more first semiconductor dies on a carrier;
forming a first mold layer surrounding the one or more first semiconductor dies;
forming a plurality of openings through the first mold layer;
filling the plurality of openings with conductive filler to form a plurality of through mold vias (TMVs) through the first mold layer; and
placing a semiconductor package on the first mold layer, the semiconductor package comprising:
a redistribution layer;
one or more second semiconductor dies electrically connected to the redistribution layer;
a second mold layer surrounding the one or more second semiconductor dies; and
a plurality of interconnects attached to the redistribution layer,
wherein placing the semiconductor package on the first mold layer buries the plurality of interconnects in the conductive filler of respective TMVs of the plurality of TMVs.

17. The method of claim 16, further comprising:
removing the carrier; and
applying a plurality of solder balls to respective TMVs of the plurality of TMVs and to respective direct chip attachment (DCA) bumps of the one or more first semiconductor dies.

18. The method of claim 16, further comprising:
forming an additional redistribution layer on the carrier,
wherein the one or more first semiconductor dies are placed on the additional redistribution layer that is on the carrier.

19. The method of claim 18, further comprising:
removing the carrier; and
applying a plurality of solder balls to the additional redistribution layer.

20. The method of claim 16, further comprising:
forming the redistribution layer;
placing the one or more second semiconductor dies on the redistribution layer;
forming the second mold layer surrounding the one or more second semiconductor dies; and
applying the plurality of interconnects to the redistribution layer.
